(19) United States
(12) Patent Application Publication
(10) Pub. No.: US 2008/0078996 A1
(43) Pub. Date: Apr. 3, 2008

(54) Semiconductor Device and Method of Manufacturing the Same

(76) Inventor: Koji USUDA, Yokohama-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/855,331

(22) Filed: Sep. 14, 2007

(30) Foreign Application Priority Data
Sep. 28, 2006 (JP) 2006-265507

(51) Int. Cl. H01L 23/58; H01L 21/66

(52) U.S. Cl. 257/48; 438/14; 257/E21.521; 257/E29.043

(57) ABSTRACT

A semiconductor device in accordance with one embodiment of the present invention includes: a strained semiconductor layer formed on a substrate; and a strain measuring region, provided on the substrate, for measuring a strain of the semiconductor layer. The semiconductor device may further include: a reference information measuring region, provided on the substrate, for measuring reference information for evaluating the strain of the semiconductor layer.

### CROSS REFERENCE TO RELATED APPLICATION

This application is based upon and claims the benefit of priority from the prior Japanese Patent Application No. 2006-265507, filed on Sep. 28, 2006, the entire contents of which are incorporated herein by reference.

### BACKGROUND OF THE INVENTION

1. Field of the Invention

The present invention relates to a semiconductor device and a method of manufacturing the same, for example, a semiconductor device including a strained semiconductor layer such as a strained Si layer or a strained SiGe layer, and a method of manufacturing the same.

2. Background Art

The performance of Si-LSI semiconductor elements, particularly, the performance of Si-MOSFETs, has been improved year after year along with the advance of LSI technology. However, it has been pointed out recently from the viewpoint of process technology that a lithographic technology has reached its limit, and pointed out from the viewpoint of element physics that the improvement of carrier mobility has been saturated. Therefore, it has become increasingly difficult to further improve the performance of Si-LSI semiconductor elements.

In recent years, as a method of increasing electron mobility, a technology of applying “strain” to an active layer has attracted attention. Electron mobility is one of the indexes used for improving the performance of Si-MOSFETs. When strain is applied to the active layer, the band structure of the active layer is changed and carrier scattering within a channel is constrained, which improves electron mobility. Specifically, a mixed crystal layer made of material having a lattice constant greater than that of Si, is formed on an Si substrate, an example of the mixed crystal layer being a strain-relaxed SiGe mixed crystal layer (hereinafter simply described as an SiGe layer) having a 20% Ge concentration; then an Si layer is formed on the SiGe layer; this results in the formation of a strained Si layer to which a strain due to the difference between the lattice constants is applied. It has been reported that if such a strained Si layer is used for the channel, the electron mobility can be dramatically improved; the electron mobility in the case is approximately 1.76 times larger than that in a case where a non-strained Si layer is used for the channel (refer to, for example, “J. Welser, J. L. Hoyl, S. Takagi, and J. F. Gibbons, IEDM 94-373”).

Furthermore, as a method of forming a strained Si channel on an SOI (Semiconductor On Insulator) structure, there is known a method of forming a strained Si layer on an SiGe layer formed on a buried oxide (BOX) layer on an Si substrate (refer to, for example, “T. Mizuno, et al., 11-3, 2002 Symposia on VLSI Tech”). According to the above-described structure, the short channel effect (SCE) of a MOSFET is constrained, so that a high-performance semiconductor element is realized.

In order to achieve further performance improvements in semiconductor elements along with the progress of miniaturization, more advanced strain control technique is required. Recently, it has been shown that the characteristics of a semiconductor element can be improved more than ever, by using a channel layer having a so-called “uniaxial strain”, wherein strain is applied in the desired direction, in place of a channel layer having a so-called “biaxial strain” wherein strain is applied in Lg/Wg directions parallel to the channel plane (refer to, for example, “T. Irisawa et al., IEEE, Symp. on VLSI Tech. (2005) 10A-3”).

The size of an active layer for forming elements is considered to become increasingly smaller in the future. In an “hp22-generation” semiconductor element for which the above-described strained semiconductor element is likely to be used, the gate length of the channel in the carrier movement direction, Lg, is considered to be 10 nm or shorter. As a result, a strain applied to the active layer due to an element structure is expected to become greater along with miniaturization. For example, a gate electrode and a cap layer may provide strains to the active layer. These strains may contribute to improving or otherwise deteriorating the element characteristics, depending on the way these strains are applied to the active layer. Furthermore, with regard to a semiconductor element wherein a channel layer is formed on an SOI structure, it is also expected that the channel layer come to be more thinned and a semiconductor element be formed on a thin channel layer having a thickness of a several tens of nanometers or less. Then, it is concerned that depending on a method of miniaturizing and thinning materials for forming a semiconductor device, the materials be deformed due to strains inherent therein and there occur unintended strain changes, such as inclination or warpage.

Strain measurement is a useful method to evaluate the characteristics of a strained semiconductor device. Raman measurement method is one of the most widely used strain measurement methods of today. However, since the spot diameter of laser light used for the Raman measurement method is normally in the order of submicrons and measurement results available from the method are average information within a measured region, it is impossible to evaluate a strain applied in the desired direction of the channel layer of the strained semiconductor element using the Raman measurement method. Furthermore, the characteristics of the strained semiconductor element need to be improved by precisely evaluating a strain distribution within the channel plane. However, since the size of the channel region is as small as several nanometers to several tens of nanometers, it is difficult to directly measure the strain of the channel layer using the Raman measurement method.

As discussed above, the strained semiconductor element has the possibility of an unintended strain being applied due to miniaturizing and thinning the channel layer, which results in a deterioration in the element characteristics of the strained semiconductor element. The strained semiconductor element has had a problem that despite this possibility, it is difficult to precisely and directly evaluate the strain and to perform strain control. Furthermore, despite the importance of controlling the direction of strain application for the improvement of the element characteristics, even direct strain evaluation has been difficult to achieve and, therefore, strain distribution control has been virtually an unattainable desire.

### SUMMARY OF THE INVENTION

An embodiment of the present invention is, for example, a semiconductor device including:

a strained semiconductor layer formed on a substrate; and

a strain measuring region, provided on the substrate, for measuring a strain of the semiconductor layer.

Another embodiment of the present invention is, for example, a semiconductor device including:

an insulating layer formed on a substrate;

an island-shaped strained semiconductor layer formed on the insulating layer; and

a strain measuring region, provided on the substrate, for measuring a strain of the semiconductor layer, the strain measuring region having the semiconductor layer, wherein at least a part of the substrate below the semiconductor layer is removed or thinned.

Another embodiment of the present invention is, for example, a semiconductor device including:

a substrate;

a strained semiconductor layer formed on the substrate, in a real transistor section on the substrate;

a gate insulating film formed on the semiconductor layer, in the real transistor section on the substrate;

a gate electrode formed on the gate insulating film, in the real transistor section on the substrate;

a strained semiconductor layer formed on the substrate, in a strain measuring section on the substrate;

a strain measuring region, provided in the strain measuring section on the substrate, for measuring a strain of the semiconductor layer; and

a reference information measuring region, provided in the strain measuring section on the substrate, for measuring reference information for evaluating the strain of the semiconductor layer.

Another embodiment of the present invention is, for example, a method of manufacturing a semiconductor device, the method including:

forming a strained semiconductor layer on a substrate; and

providing, on the substrate, a strain measuring region for measuring a strain of the semiconductor layer.

Another embodiment of the present invention is, for example, a method of manufacturing a semiconductor device, the method including:

preparing a substrate whereon an insulating layer is formed;

forming an island-shaped strained semiconductor layer on the insulating layer; and

providing, on the substrate, a strain measuring region for measuring a strain of the semiconductor layer, the strain measuring region having the semiconductor layer, wherein at least a part of the substrate below the semiconductor layer is removed or thinned.

Another embodiment of the present invention is, for example, a method of manufacturing a semiconductor device, the method including:

preparing a substrate;

forming a strained semiconductor layer on the substrate, in a real transistor section on the substrate;

forming a gate insulating film on the semiconductor layer, in the real transistor section on the substrate;

forming a gate electrode on the gate insulating film, in the real transistor section on the substrate;

forming a strained semiconductor layer on the substrate, in a strain measuring section on the substrate;

providing a strain measuring region for measuring a strain of the semiconductor layer, in the strain measuring section on the substrate; and

providing a reference information measuring region for measuring reference information for evaluating the strain of the semiconductor layer, in the strain measuring region on the substrate.

### BRIEF DESCRIPTION OF THE DRAWINGS

FIG. 1 is a projected cross-sectional view illustrating the element structure of a semiconductor device 101 in accordance with a first embodiment of the present invention;

FIG. 2 is a schematic view intended to explain a method of evaluating a diffraction image 202A based on a diffraction image 202B;

FIG. 3 shows side cross-sectional views illustrating element structures of a semiconductor device 101 in accordance with a second embodiment of the present invention;

FIG. 4 is a top cross-sectional view intended to explain a method of constraining a warpage of a strained SiGe layer 113;

FIG. 5 is a projected cross-sectional view illustrating the element structure of a semiconductor device 101 in accordance with a third embodiment of the present invention;

FIG. 6 is a top cross-sectional view intended to explain the uniaxially-strained and biaxially-strained regions of a strained SiGe layer 113;

FIG. 7 shows a side cross-sectional view illustrating the element structure of a semiconductor device 101 in accordance with a fourth embodiment of the present invention; and

FIGS. 8A to 8E are process diagrams intended to explain a method of manufacturing a semiconductor device 101.

### DESCRIPTION OF THE EMBODIMENTS

Embodiments of the present invention will be described hereinafter with reference to the accompanying drawings.

### First Embodiment

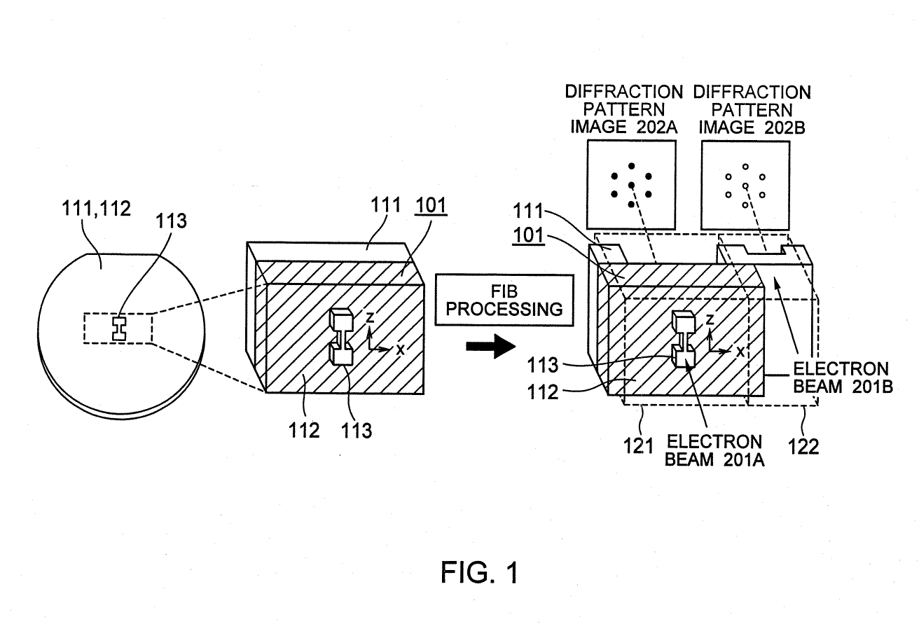

FIG. 1 is a projected cross-sectional view illustrating the element structure of a semiconductor device 101 in accordance with a first embodiment of the present invention.

In the semiconductor device 101 illustrated in FIG. 1, an insulating layer 112 is formed on an Si substrate 111, and an island-shaped strained SiGe layer 113 formed in a mesa form is formed on the insulating layer 112. The Si substrate 111 is a semiconductor substrate made of Si (silicon), and is an example of a substrate in accordance with the present invention. The thickness of the Si substrate 111 is approximately 600 nm here. The insulating layer 112 is a buried insulating layer (buried oxide layer) made of SiO₂ (silicon oxide), and is an example of an insulating layer in accordance with the present invention. The thickness of the insulating layer 112 is approximately 150 nm here. The strained SiGe layer 113 is a strained semiconductor layer made of SiGe (silicon germanium), and is an example of a strained semiconductor layer in accordance with the present invention. The thickness of the strained SiGe layer 113 is approximately 100 nm here.

In general, an SiGe thin film is formed by chemical vapor deposition (CVD) process, molecular beam epitaxy (MBE) process, or the like. When the strained SiGe layer 113 is formed, for example, by CVD process, an SOI substrate including the Si substrate 111, the insulating layer 112, and an Si layer is prepared, an SiGe layer is formed on the SOI substrate heated to 550° C. using a raw material Si gas and a raw material Ge gas, and oxidation in an oxygen atmosphere, such as an enrichment method (T. Tezuka et al., IEDM Tech. Dig., 946 (2001)), is performed, so that an SOI substrate including the Si substrate 111, the insulating layer 112, and the strained SiGe layer 113 is formed. Such an SOI substrate may be formed by forming the strained SiGe layer 113, using a bonding method, on the insulating layer 112 formed on the Si substrate 111, directly or via an insulating layer such as an oxide layer.

Although the strained semiconductor layer 113 is an SiGe layer here, the layer may be another semiconductor layer other than the SiGe layer. For example, the strained semiconductor layer 113 may be a semiconductor layer containing at least one of carbon (C), nitrogen (N), oxygen (O), silicon (Si), germanium (Ge), gallium (Ga), arsenic (As), indium (In), antimony (Sb), hafnium (Hf), tantalum (Ta), tungsten (W), nickel (Ni), platinum (Pt), and gold (Au). Examples of such a strained semiconductor layer 113 include an SiC layer, an SiN layer, an HfO₂ layer, a GaN layer, a GaAs layer, and the like.

In the semiconductor device 101 illustrated in FIG. 1, the Si substrate 111 is provided with a strain measuring region 121 and a reference information measuring region 122. The strain measuring region 121 is a region for measuring a strain of the strained SiGe layer 113. The reference information measuring region 122 is a region for measuring reference information for evaluating the strain of the strained SiGe layer 113. The strain measuring region 121 and the reference information measuring region 122 are provided on the Si substrate 111. In the strain measuring region 121, there exist the strained SiGe layer 113 and the insulating layer 112, and the Si substrate 111 below the strained SiGe layer 113 is removed. In the reference information measuring region 122, the strained SiGe layer 113 and the insulating layer 112 are removed in an area, and the Si substrate 111 below the area is thinned to such a thickness as to enable electron beam diffraction. Note that the processing of the strain measuring region 121 and the reference information measuring region 122 can be performed, for example, by focused ion beam (FIB) processing.

The thickness of the thinned part of the Si substrate 111 is preferably in the range from 5 to 500 nm, particularly, in the range from 100 to 300 nm. The thickness of the thinned part is approximately 200 nm here. In addition, the Si substrate 111 included in the strain measuring region 121 may be removed only partially as shown in FIG. 1, or may otherwise be removed entirely. Likewise, the insulating layer 112 included in the reference information measuring region 122 may be removed only partially as shown in FIG. 1, or may otherwise be removed entirely. Likewise, the strained SiGe layer 113 included in the reference information measuring region 122 may be removed entirely as shown in FIG. 1, or may otherwise be removed only partially.

Although the Si substrate 111 included in the strain measuring region 121 is removed here, the Si substrate 111 included in the strain measuring region 121 may be thinned. In this case, the thinned part of the Si substrate 111 included in the strain measuring region 121 is preferably as thick as not to disturb electron beam diffraction. The thickness of the thinned part is, for example, 300 nm or less, preferably, 10 nm or less. The Si substrate 111 included in the strain measuring region 121 may be thinned only partially or may otherwise be thinned entirely, like in the case of removal.

In strain measurement in the present embodiment, there are performed electron beam irradiation at the strain measuring region 121 and diffraction image measurement thereof. Specifically, an electron beam 201A of 10 nm in diameter is projected from the topside of the Si substrate 111 onto the top surface of the strained SiGe layer 113 in the strain measuring region 121, and a diffraction image (diffraction pattern image) 202A of the electron beam 201A is recorded in a diffraction image monitor at the backside of the Si substrate 111. Alternatively, the electron beam 201A may be projected from the backside of the Si substrate 111, and the diffraction image 202A may be recorded at the topside of the Si substrate 111.

In addition, in strain measurement in the present embodiment, there are performed electron beam irradiation at the reference information measuring region 122 and diffraction image measurement thereof. Specifically, an electron beam 201B of 10 nm in diameter is projected from the topside of the Si substrate 111 onto the top surface of the Si substrate 111 in the reference information measuring region 122, and a diffraction image (diffraction pattern image) 202B of the electron beam 201B is recorded in a diffraction image monitor at the backside of the Si substrate 111. Alternatively, the electron beam 201B may be projected from the backside of the Si substrate 111, and the diffraction image 202B is recorded at the topside of the Si substrate 111.

From the result of measurement of the diffraction image 202A, it is possible to evaluate the lattice constant or a variation in the lattice constant of the strained SiGe layer 113. In the present embodiment, the result of measurement of the diffraction image 202A is utilized to evaluate the strain of the strained SiGe layer 113. Likewise, from the result of measurement of the diffraction image 202B, it is possible to evaluate the lattice constant of the Si substrate 111. In the present embodiment, the result of measurement of the diffraction image 202B is utilized as reference information for evaluating the strain of the strained SiGe layer 113. Accordingly, in the present embodiment, it is possible to evaluate the strain of the strained SiGe layer 113 based on absolute value evaluation, by evaluating the diffraction image 202A of the strained SiGe layer 113 on the basis of the diffraction image 202B of the Si substrate 111 which can be regarded as being constant. Consequently, in the present embodiment, the strain of each semiconductor layer of each semiconductor device can be compared with the strain of another semiconductor layer of the same or a different semiconductor device.

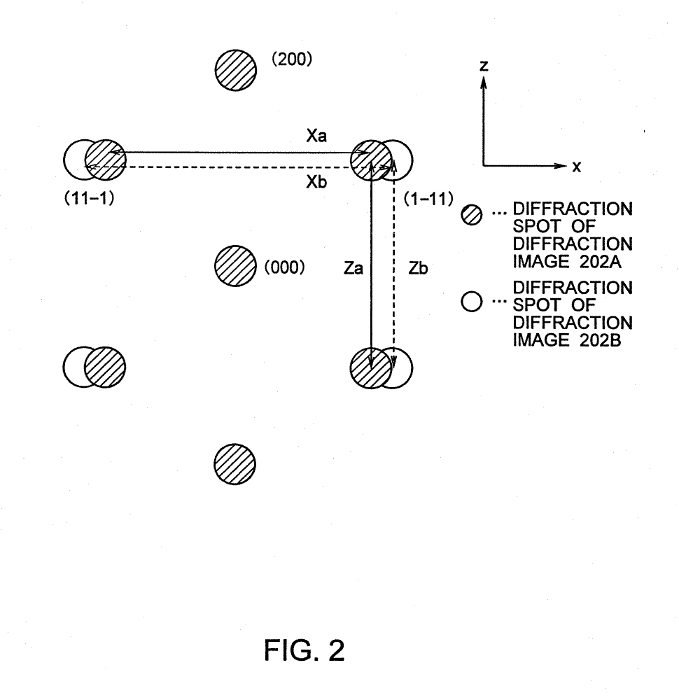

Now, an explanation will be made, with regard to a method of evaluating the diffraction image 202A on the basis of the diffraction image 202B. FIG. 2 illustrates diffraction spots of the diffraction image 202A indicated by shaded circles and diffraction spots of the diffraction image 202B indicated by white circles, which are overlapped by positioning their diffraction spots (000) at the same position.

First, since a spot-to-spot distance of the diffraction image 202A in the “X” direction, Xa, is approximately 0.99 times the corresponding spot-to-spot distance of the diffraction image 202B, Xb, it is understood that in the irradiated region of the electron beam 201A, the lattice constant of the strained SiGe layer 113 in the “X” direction (see FIG. 1) is approximately 1.01 times (≈1/0.99) that of the Si substrate 111 in the “X” direction.

Second, since the spot-to-spot distance of the diffraction image 202A in the “Z” direction, Za, is almost equal to the corresponding spot-to-spot distance of the diffraction image 202B, Zb, it is understood that in the irradiated region of the electron beam 201A, the lattice constant of the strained SiGe layer 113 in the “Z” direction (see FIG. 1) is almost the same as (i.e., approximately one time) that of the Si substrate 111 in the “Z” direction.

Accordingly, it is understood from FIG. 2 that in the irradiated region of the electron beam 201A, the strain of the strained SiGe layer 113 has been relaxed uniaxially in the “X” direction, and a compressive strain applied in the original state of the substrate is still maintained in the “Z” direction of the strained SiGe layer 113, therefore a so-called uniaxial strain is applied to the measuring region.

Although a method of relatively evaluating the lattice variation of strained SiGe against Si is explained in the present embodiment, it is possible to obtain the lattice constant of the strained SiGe from the lattice constant of the Si substrate if the lattice constant of the Si substrate is previously known. The lattice constant of Si, if measured using a regular X-ray diffraction method, can be easily determined to an accuracy of approximately five decimal digits. Therefore, it has an accuracy sufficient for determining the lattice constant of the measuring region, with an accuracy based on the electron beam diffraction of the present method (Δd/d˜0.1%: approximately four digits). Consequently, in a case where there is a remarkable lattice constant distribution in an Si substrate, such as if the Si substrate has a remarkable warpage, it is desirable that a standard lattice constant of the Si substrate be previously measured in the vicinity of an area where electron beam diffraction is caused.

Since the diffraction images 202A and 202B are two-dimensional images in the present embodiment, it is possible to evaluate the lattice constants of the strained SiGe layer 113 and the Si substrate 111 in the “X” and “Z” directions from the diffraction images 202A and 202B, as described above. Accordingly, in the present embodiment, the strain of each strained semiconductor layer of each semiconductor device can be evaluated separately in two directions. This is useful when, for example, only a uniaxial strain in one direction needs to be measured with regard to a region where the uniaxial strain is applied in two directions as shown in FIG. 2. In addition, in the present embodiment, the diameters of the electron beams 201A and 201B are approximately 10 nm and can be said to be suited for the evaluation of the strain and strain distribution of the strained SiGe layer 113.

Examples of a method for measuring a diffraction image for analysis include recording the diffraction image projected onto an image surface (such as a fluorescent plate) on a photographic paper or the like, and capturing the diffraction image in a charge-coupled device (CCD). Although an interval between diffraction spots varies depending on a distance between a sample and an image surface and on the acceleration energy of an electron beam, the interval is in the order of approximately millimeters to centimeters.

In the present embodiment, as a beam for strain measurement, a beam other than an electron beam, capable of measuring the lattice constant of a crystal lattice, may be used in place of an electron beam. For example, an X ray may be used in place of an electron beam. Alternatively, a neutron beam, an ion beam or an intense light beam, which can pass through the Si substrate 111 and is diffracted by a crystal lattice, may be used. The beam to be used is preferably such a beam as can accurately measure the lattice constant of a crystal lattice. In addition, the beam to be used is preferably such a beam as to enable obtaining two-dimensional diffraction images so that the strain of the strained SiGe layer 113 can be evaluated separately in two directions. The strain measuring region 121 and the reference information measuring region 122 are configured so that the beam to be used can pass therethrough and can be diffracted thereby. For example, when carrying out the present embodiment using a regular X-ray generator for laboratory use, it is important to enhance the degree of collimation of an X-ray beam using a crystal monochromator or the like and to minimize the diameter of the X-ray beam. The X-ray beam is required to have a degree of collimation as high as 10 milliradian in terms of a divergence angle and, more preferably, as high as 10e⁻¹ milliradian.

Now, an explanation will be made, with regard to the measurement accuracy of the lattice constant d of the strained SiGe layer 113.

In the present embodiment, the electron beam 201A is projected perpendicular to the strained SiGe layer 113, the spot position of the diffraction image 202A is determined by the three-dimensional fitting of a spot shape and an intensity distribution, and the spot position of the diffraction image 202A is compared with that of the diffraction image 202B from the Si substrate 111; thereby, the lattice constant d of the strained SiGe layer 113 can be evaluated with an accuracy of approximately Δd/d˜±0.1%.

On the other hand, if the directions of incidence of the electron beams 201A and 201B are tilted from the vertical direction, three-dimensional diffraction images, such as Holts lines, can be obtained as the diffraction images 202A and 202B. Accordingly, in the present embodiment, it is possible to evaluate the lattice constant d of the strained SiGe layer 113, i.e., the strain of the strained SiGe layer 113, separately in three directions. In this case, the lattice constant d of the strained SiGe layer 113 can be evaluated with an accuracy of approximately Δd/d˜±0.02%. However, if the electron beams 201A and 201B are projected obliquely to the substrate surface (measuring plane), the spatial resolution is broadened depending on the angle of incidence. Especially, if the structure of elements positioned along the direction of entry of the electron beams 201A and 201B becomes uneven along with the advance of element miniaturization, it may become unable to obtain precise strain information. For this reason, the angles of incidence of the electron beams 201A and 201B are preferably perpendicular to the substrate surface (measuring plane) or otherwise no greater than 12 degrees.

The strain measuring region 121 and the reference information measuring region 122 of the present embodiment may be formed either before or after wafer dicing. In the former case, the process of forming the both regions and the process of strain measurement can be carried out as part of a so-called front-end process, and the result of the strain measurement based on the both regions can be reflected in the process of forming semiconductor elements (front-end process). Note that the strain measurement may also be carried out either before or after the wafer dicing.

As described above, in the present embodiment, it is possible to evaluate strains by absolute value evaluation and by separate evaluation in two or three directions. Accordingly, in the present embodiment, it is possible to efficiently set forward the consideration of conditions of a strain formation process and the failure analysis of semiconductor elements. Consequently, according to the present embodiment, it is possible to realize high-performance semiconductor elements more promptly than ever while applying a sufficient strain to a strained channel. This makes it possible to achieve cost reductions by shortening development period and speeding up quality control, and to appropriately meet the requirement of further miniaturization in the future.

### Second Embodiment

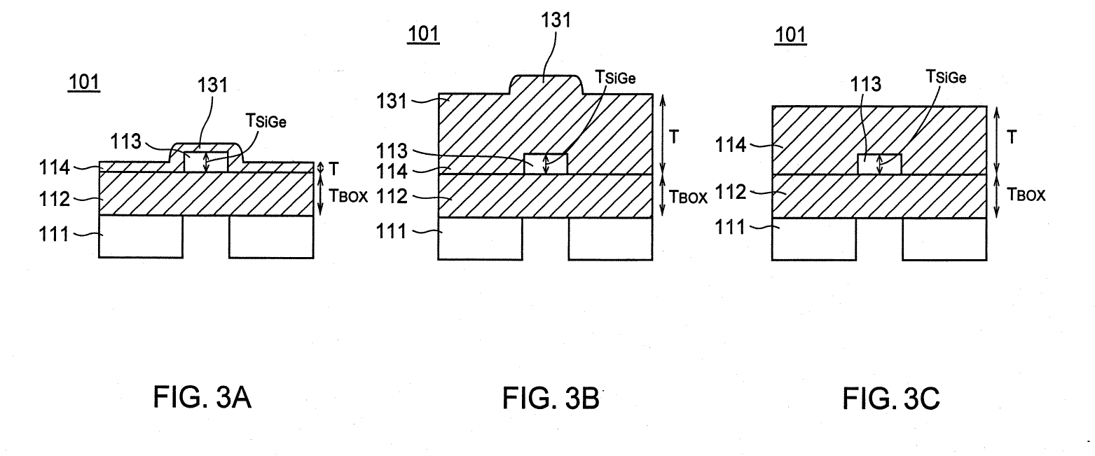

FIG. 3 shows side cross-sectional views illustrating element structures of a semiconductor device 101 in accordance with a second embodiment of the present invention. The second embodiment will be described with a focus on differences from the first embodiment.

In the semiconductor device 101 illustrated in FIG. 3A, a strained SiGe layer 113 is sandwiched between an insulating layer 112 adjacent to the bottom surface of the strained SiGe layer 113 and an insulating layer 114 adjacent to the top surface of the strained SiGe layer 113. The former insulating layer 112 here is a buried insulating layer (buried oxide layer) made of SiO₂ (silicon oxide), and the latter insulating layer 114 here is an interlayer insulating layer (interlayer oxide layer) made of SiO₂. The insulating layer 112 configures an SOI substrate with an Si substrate 111, and the insulating layer 114 is formed on a real transistor on the Si substrate 111. The insulating layer 112 adjacent to the bottom surface of the strained SiGe layer 113 may be another insulating layer other than a buried insulating layer, and the insulating layer 114 adjacent to the top surface of the strained SiGe layer 113 may be another insulating layer other than an interlayer insulating layer.

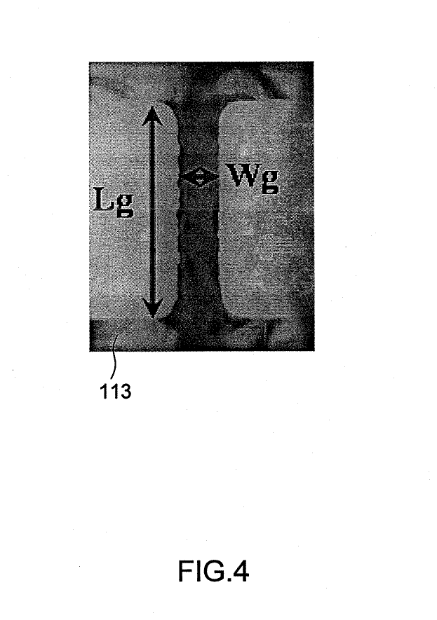

In the present embodiment, since the strained SiGe layer 113 is sandwiched between the insulating layer 112 adjacent to the bottom surface of the strained SiGe layer 113 and the insulating layer 114 adjacent to the top surface of the strained SiGe layer 113, the warpage of the strained SiGe layer 113 is constrained. Here, the top cross-sectional view of the strained SiGe layer 113 is shown in FIG. 4 with Lg/Wg. In the strained SiGe layer 113 shaped as shown in FIG. 4, there is a concern over warpage in the “Lg” direction in particular. In the present embodiment, however, this warpage in the “Lg” direction is constrained by the effect of the insulating layers 112 and 114. Note that various conditions that are preferably satisfied are conceivable with regard to the thickness of the insulating layer 112 “T_{BOX}”, the thickness of the strained SiGe layer 113 “T_{SiGe}”, and the thickness of the insulating layer 114 “T”. These conditions will be described hereinafter.

The strain measurement of the semiconductor device illustrated in FIG. 3A may be difficult to achieve, depending on the thicknesses of the insulating layers 112 and 114. For example, when an electron beam is accelerated at 300 keV and is adjusted to a diameter of 10 nm, the intensity of a transmitted electron beam decreases drastically if the thicknesses of the insulating layers 112 and 114 exceed 1000 nm in total. In addition, diffraction peaks are broadened due to fluctuations in the intensity and the distribution of the electron beam and noise in the electron beam. Consequently, it comes to be difficult to perform accurate strain measurement. Accordingly, when setting the acceleration voltage and the diameter of the electron beam as described above, the total thickness of the insulating layers 112 and 114 “T_{BOX}+T” is preferably no greater than 1000 nm in terms of the thickness of silicon dioxide. It has been experimentally confirmed that the total thickness of no greater than 500 nm in terms of the thickness of silicon dioxide is especially effective. Such acceleration voltage and diameter settings as described above are typical as electron beam settings for strain measurement. Therefore, the conditions of “T_{BOX}+T” being no greater than 1000 nm or 500 nm can be said to be highly generic conditions. Note that if a higher acceleration voltage, 600 keV for example, is realized in the future, the transmission capability of the electron beam increases in proportion to the increment of the acceleration voltage. In addition, the threshold of conditions of “T_{BOX}+T” also increases.

Furthermore, it has turned out that strain measurement may become inaccurate in a case where the insulating layer 114 is absent, the thickness of the insulating layer 114 “T” is less than the thickness of the strained SiGe layer 113 “T_{SiGe}”, or the thickness of the insulating layer 114 “T” is greater than twice the thickness of the insulating layer 112 “T_{BOX}” (FIG. 3B). In a case where only one of the top and bottom surfaces of the strained SiGe layer 113 is adjacent to an insulating layer, insulating layers above and below the strained SiGe layer 113 are extremely thin, or the overlying and underlying insulating layers significantly differ in thickness from each other, a warpage is easy to occur in the strained SiGe layer 113; this is considered to be the cause of the above-mentioned inaccuracy. Such warpage disturbs electron beam diffraction and causes the inaccuracy in strain measurement. From the above-described points of view, it can be said to be desirable that “2T_{BOX}≧T≧T_{SiGe}” holds true for the thickness of the insulating layer 112 “T_{BOX}”, the thickness of the strained SiGe layer 113 “T_{SiGe}”, and the thickness of the insulating layer 114 “T”. Consequently, it is possible to more effectively prevent post-processing deformations (e.g., warpage) in the strained SiGe layer 113. Especially, it has turned out that more accurate strain measurement can be performed by making “T=T_{SiGe}+T_{BOX}” hold true.

The conditions that are preferably satisfied vary also depending on the strain, thickness, and size of the strained SiGe layer 113. For example, if the strain of the strained SiGe layer 113 is as small as 2 GPa or less, the overlying and underlying insulating layers may be thinned as much as possible. Specifically, even if the thickness of the underlying insulating layer 112 “T_{BOX}” is no greater than 1 nm in terms of the thickness of silicon dioxide, accurate strain measurement may be feasible in some cases. In this case, the thickness of the overlying insulating layer 114 “T” preferably satisfies “T≧T_{BOX}+1 nm” in terms of the thickness of silicon dioxide. The thickness of the strained SiGe layer 113 “T_{SiGe}” is preferably no greater than 500 nm.

Furthermore, even if the member adjacent to the bottom surface of the strained SiGe layer 113 is not an insulating material, it is possible to prevent post-processing deformations in the strained SiGe layer 113. For example, the member adjacent to the bottom surface of the strained SiGe layer 113 may be a crystal layer (Si layer for example) or an amorphous layer. In this case, the total thickness of the underlying crystal layer and the overlying insulating layer is preferably no greater than 500 nm and, for practical purposes, no greater than 300 nm.

In the present embodiment, since the strained SiGe layer 113 is shaped in an island form, a convex portion 131 is formed in the insulating layer 114 above the strained SiGe layer 113 as illustrated in FIG. 3A or FIG. 3B, when the insulating layer 114 is formed over the strained SiGe layer 113. As a result, a change may occur in the transmission strength of an electron beam at the shoulders or the like of the convex portion 131 during strain measurement, which may degrade measurement accuracy.

Hence in the present embodiment, when forming the insulating layer 114 over the strained SiGe layer 113, the thickness of the insulating layer 114 “T” is made to be greater than “T_{SiGe}+T_{BOX}”. Then, the convex portion 131 formed at the time is planarized by chemical mechanical polishin (CMP), FIB processing, or etching, as shown in FIG. 3C. Thereby, the problem of deterioration in strain measurement accuracy due to the convex portion 131 is avoided. Concurrently, the ideal condition “T=T_{SiGe}+T_{BOX}” is realized by carrying out planarization so that the thickness of the insulating layer 114 “T” equals “T_{SiGe}+T_{BOX}”. Although the convex portion 131 of the insulating layer 114 is planarized after the formation of the insulating layer 114 here, the insulating layer 114 may be formed using a forming method whereby the top surface of the insulating layer 114 is planarized.

### Third Embodiment

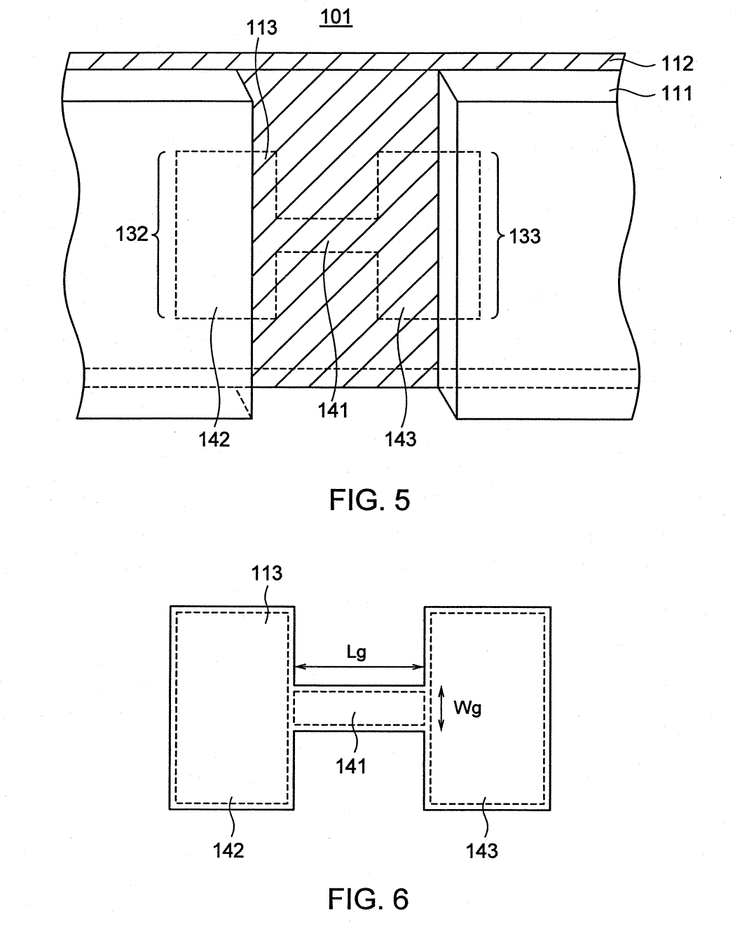

FIG. 5 is a projected cross-sectional view illustrating the element structure of a semiconductor device 101 in accordance with a third embodiment of the present invention. The third embodiment will be described with a focus on differences from the first embodiment.

Before entering into the description of the semiconductor device illustrated in FIG. 5, there will be described the structure of a strained SiGe layer 113. Here, the top cross-sectional view of the strained SiGe layer 113 is shown in FIG. 6 with Lg/Wg. As shown in FIG. 6, the strained SiGe layer 113 is shaped in an H form. In the center of the strained SiGe layer 113, there is provided a uniaxially-strained region 141 having a uniaxial strain and, at both ends of the strained SiGe layer 113, there are respectively provided a first biaxially-strained region 142 having a biaxial strain and a second biaxially-strained region 143 having a biaxial strain.

In the uniaxially-strained region 141, a uniaxial compressive strain is applied in the “Lg” direction, and a relaxed uniaxial strain is applied in the “Wg” direction. The uniaxially-strained region 141 corresponds to the channel region of a real transistor. It is the uniaxial compressive strain applied in the “Lg” direction that contributes to enhancing the carrier mobility of this channel region of the real transistor. Accordingly, an object of the present embodiment is to appropriately control this uniaxial compressive strain, which is the object of strain measurement.

At both ends of the strained SiGe layer 113 in the strained direction of the uniaxial compressive strain (Lg direction), there are respectively provided the first biaxially-strained region 142 and the second biaxially-strained region 143. The first and second biaxially-strained regions 142 and 143 are adjacent to the uniaxially-strained region 141. The first and second biaxially-strained regions 142 and 143 are provided so as to support the uniaxially-strained region 141 from both sides thereof, thereby maintaining the uniaxial compressive strain of the uniaxially-strained region 141. The uniaxial tensile strain of the uniaxially-strained region 141 is relaxed as there is no support on both sides thereof.

Now, the semiconductor device illustrated in FIG. 5 will be described hereinafter.

In the semiconductor device 101 illustrated in FIG. 5, the Si substrate 111 is removed below the uniaxially-strained region 141 of the strained SiGe layer 113. Accordingly, in the present embodiment, it is possible to measure the strain of the uniaxially-strained region 141. Note that in FIG. 5, the Si substrate 111 is removed in the entire area below the uniaxially-strained region 141. Alternatively, in the present embodiment, the Si substrate 111 may only be removed in a certain area below the uniaxially-strained region 141. In other words, in the present embodiment, it suffices only if there is a region below the uniaxially-strained region 141 from where the Si substrate 111 is removed. In FIG. 5, at least a part of the Si substrate 111 is removed below the uniaxially-strained region 141. Alternatively, in the present embodiment, at least a part of the Si substrate 111 may be thinned below the uniaxially-strained region 141.

Furthermore, in the semiconductor device 101 illustrated in FIG. 5, the Si substrate 111 exists below the first end 132 and the second end 133 of the strained SiGe layer 113. In other words, in the present embodiment, both ends of the strained SiGe layer 113 are supported by the Si substrate 111. In FIG. 5, there is a region below the first biaxially-strained region 142 where the Si substrate 111 exists, and there is a region below the second biaxially-strained region 143 where the Si substrate 111 exists. In the present embodiment, both ends of the strained SiGe layer 113 are supported by the Si substrate 111 in such a structure.

The strain measuring region 121 and the reference information measuring region 122 of the present embodiment are formed, after wafer dicing, by FIB processing from an edge. For this reason, it is concerned that the strain of the strained SiGe layer 113 may be relaxed because the Si substrate 111 included in the strain measuring region 121 has been processed. In the present embodiment, however, the strain of the strained SiGe layer 113 is maintained even after the Si substrate 111 included in the strain measuring region 121 is processed, since both ends of the strained SiGe layer 113 are supported by the sufficiently thick Si substrate 111. Accordingly, in the present embodiment, it is possible to measure strain accurately.

On the other hand, in the present embodiment, when forming the strain measuring region 121 and the reference information measuring region 122 before wafer dicing, it is only necessary that either the strain measuring region 121 is completely surrounded by the Si substrate 111 as viewed horizontally or both ends of the strained SiGe layer 113 are supported by the Si substrate 111. In this case, the strain measuring region 121 and the reference information measuring region 122 are formed by processing from the backside. Positioning at the time can be done in such a manner as using the coordinates of a wafer, using a mask or the like on which element-forming positions are recorded, or using transmitted light or reflected light based on a laser or the like.

According to the present embodiment, the strain of the strained SiGe layer 113 can be maintained in spite of substrate processing after wafer dicing. Therefore, it is possible to realize accurate, prompt strain measurement at a substrate level.

According to the present embodiment, it is possible to separate a strain distribution into strain distributions on at least two independent crystal axes and measure the strain distributions simultaneously. Consequently, according to the present embodiment, it is possible to realize a high-performance semiconductor device while applying a sufficient strain to a strained channel.

As an advantage in relation to the element-forming process of the present embodiment, it can be mentioned that strain evaluation can be performed in an in-process manner prior to wafer dicing, by previously preparing a strained channel in a part of a semiconductor device. Therefore, it is possible to more promptly realize the establishment of process conditions for manufacturing a high-quality, high-performance semiconductor device, which enables to constrain the development costs of semiconductor elements.

The present embodiment is also applicable to the semiconductor device 101 with such a structure in which the uniaxially-strained region 141 having a uniaxial strain being measured is replaced with a uniaxial strain detecting region for detecting the presence or absence of a uniaxial strain. Consequently, there is realized a structure suited for examining the presence or absence of a uniaxial strain.

### Fourth Embodiment

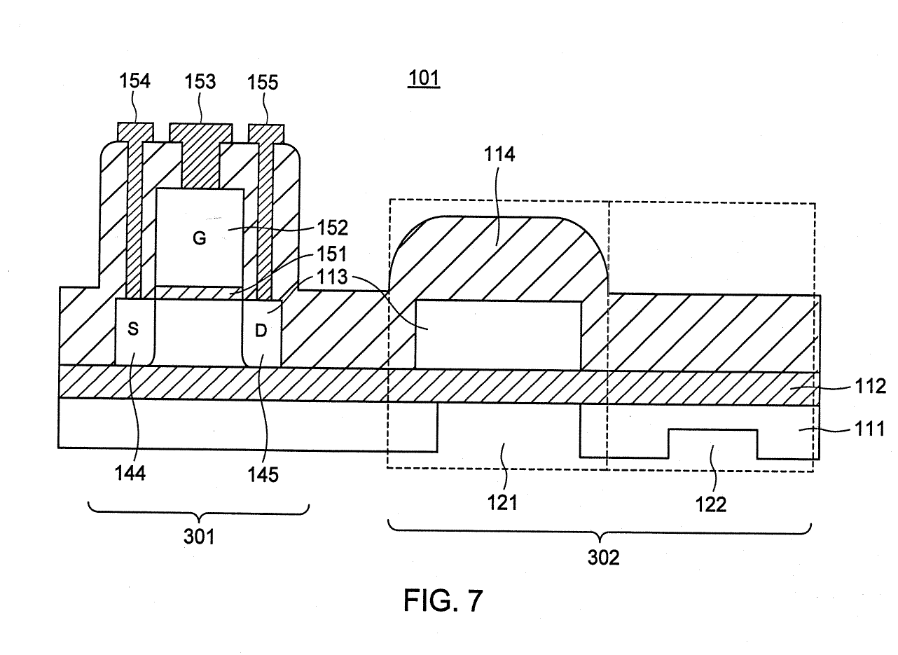

FIG. 7 shows a projected cross-sectional view illustrating the element structure of a semiconductor device 101 in accordance with a fourth embodiment of the present invention. The fourth embodiment will be described with a focus on differences from the first embodiment.

The Si substrate 111 of the semiconductor device 101 illustrated in FIG. 7 is provided with a real transistor section 301 and a strain measuring section 302. The real transistor section 301 is an area wherein a transistor to be actually used (MOSFET here) is formed. The strain measuring section 302 is an area wherein structures for strain measurement (a strain measuring region 121 and a reference information measuring region 122 here) are formed. The real transistor section 301 and the strain measuring section 302 are provided on the Si substrate 111.

As described above, in the present embodiment, a real transistor structure and a strain measuring structure are formed on the same Si substrate 111. The structure of the strain measuring region 121 may be identical to or different from that of the real MOSFET, and is only required to be appropriate for the contents of strain measurement to be carried out. When performing strain measurement after the completion of the transistor or after wafer dicing, the strain measuring region 121 and the reference information measuring region 122 may be formed immediately before strain measurement. However, when performing strain measurement in an in-process manner, the strain measuring region 121 and the reference information measuring region 122 are required to be previously formed midway through an element manufacturing process. The real transistor need not be completed by the time of strain measurement.

Now, an explanation will be made, with regard to the structures of the real transistor section 301 and the strain measuring section 302.

In the real transistor section 301, an island-shaped strained SiGe layer 113 is formed on the buried insulating layer 112 on the Si substrate 111, a gate insulating film 151 is formed on the strained SiGe layer 113, and a gate electrode 152 is formed on the gate insulating film 151. Also in the strained SiGe layer 113 of the real transistor section 301, there are provided a uniaxially-strained region 141, a first biaxially-strained region 142, and a second biaxially-strained region 143, as illustrated in FIG. 6. In the strained SiGe layer 113 of the real transistor section 301, there are further provided a source region 144 and a drain region 145. In addition, a gate line 153, a source line 154 and a drain line 155 are respectively connected to the gate electrode 152, the source region 144 and the drain region 145.

The configuration of the strain measuring section 302 is as described in the first, second and third embodiments. Note that on the strained SiGe layer 113 and the gate electrode 152 of the real transistor section 301 and on the strained SiGe layer 113 of the strain measuring section 302, there is formed a common interlayer insulating layer 114.

The ratio of the number of strained SiGe layers 113 included in the real transistor section 301 to the number of strained SiGe layers 113 included in the strain measuring section 302, on a single Si substrate 111, is about 1000:1 for example. It is only necessary that there be at least one strain measuring structure for one type of semiconductor element on a single semiconductor substrate. Preferably, it is only necessary that there be at least one measuring structure for each die (chip) disposed on a substrate.

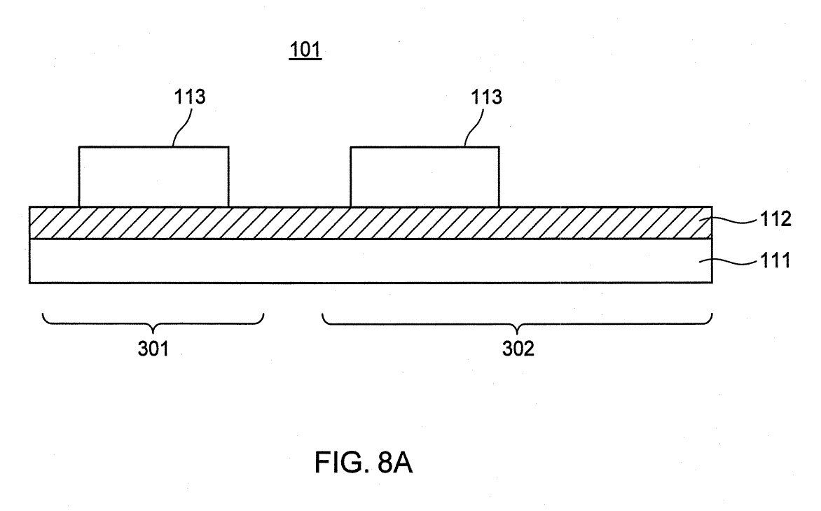

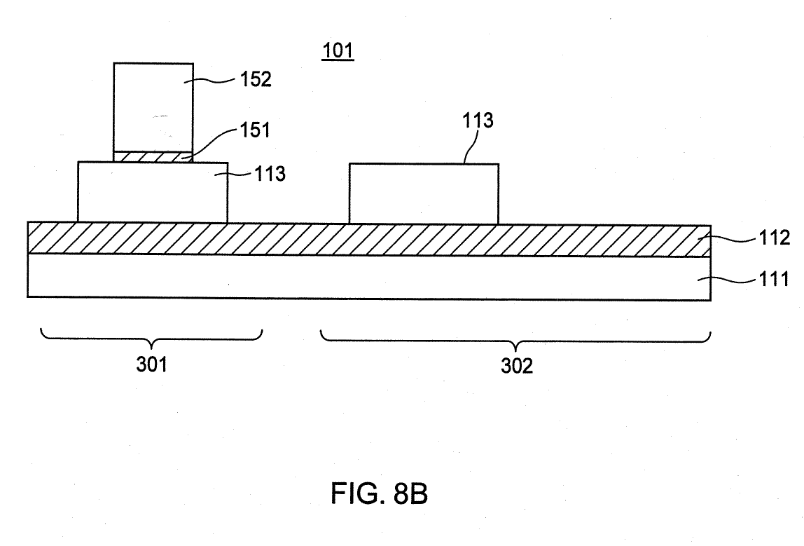

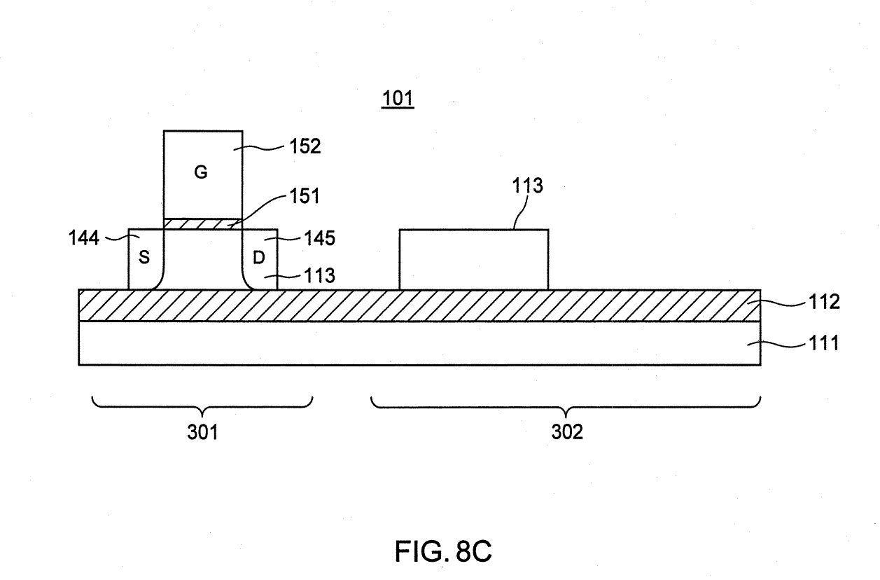

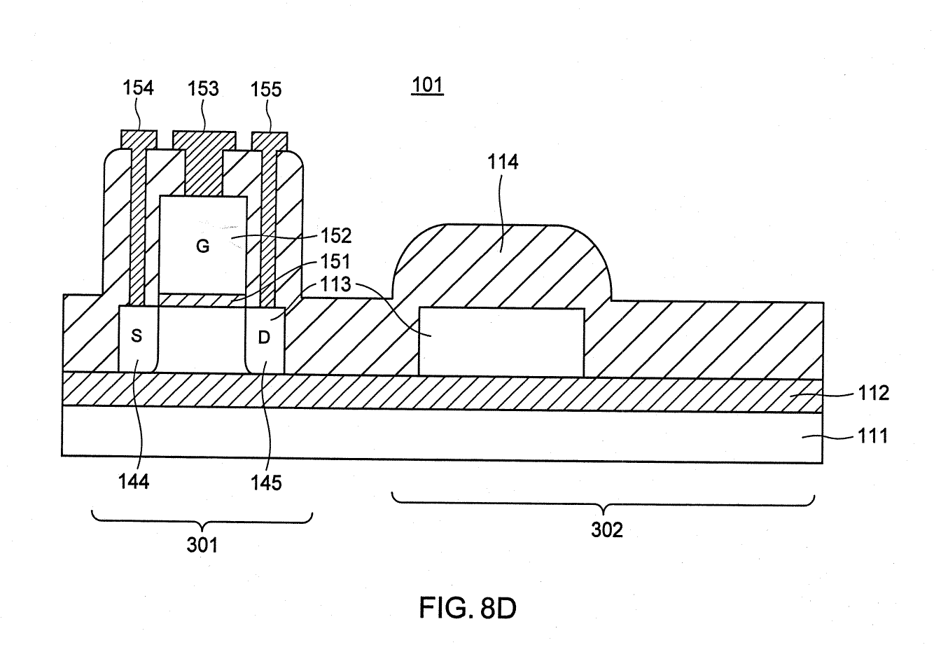

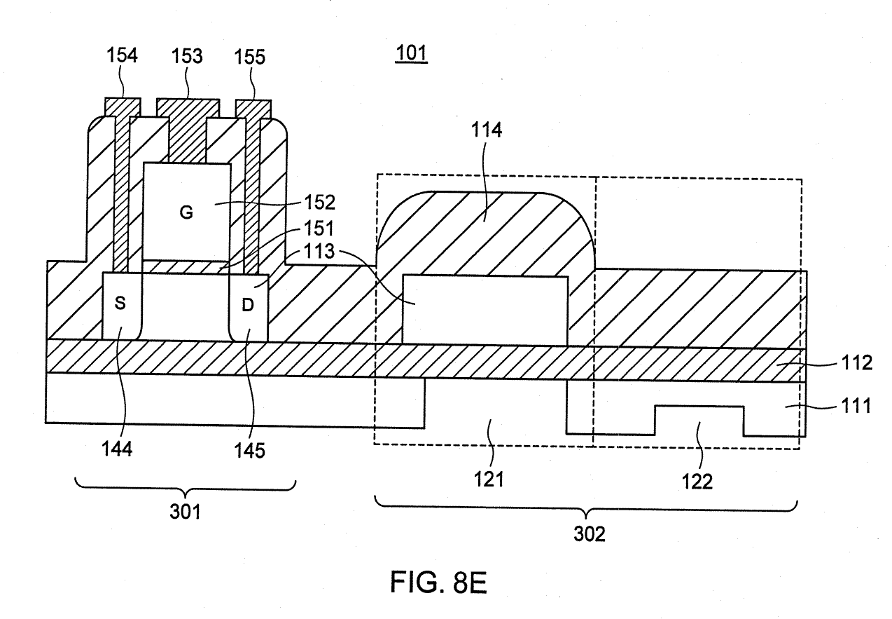

FIGS. 8A to 8E are process diagrams intended to explain a method of manufacturing a semiconductor device 101 in accordance with a fourth embodiment of the present invention.

First, as illustrated in FIG. 8A, island-shaped strained SiGe layers 113 are formed on the insulating layer 112 on the Si substrate 111, in the real transistor section 301 and the strain measuring section 302. As a method of forming the strained SiGe layers 113, such a method as described in the first embodiment or the like may be used.

Next, as illustrated in FIG. 8B, a gate insulating film (silicon oxide film, for example) 151 is formed on the strained SiGe layer 113, and a gate electrode (polysilicon electrode, for example) 152 is formed on the gate insulating film 151, in the real transistor section 301. As methods for depositing and processing a gate insulating material and a gate electrode material, publicly known methods or the like may be used.

Next, as illustrated in FIG. 8C, a source region 144 and a drain region 145 are formed in the strained SiGe layer 113, in the real transistor section 301. Then, an annealing treatment is performed on the Si substrate 111 at an anneal temperature of, for example, 1000° C. or so.

Next, as illustrated in FIG. 8D, an insulating layer 114 is formed on the Si substrate 111, in the real transistor section 301 and the strain measuring section 302. The insulating layer 114 covers the strained SiGe layer 113 and the gate electrode 152 in the real transistor section 301 and the strained SiGe layer 113 in the strain measuring section 302. Then, wiring trenches for a gate line 153, a source line 154 and a drain line 155 are formed by etching or the like in the insulating layer 114, in the real transistor section 301. Then, as illustrated in FIG. 8D, the gate line 153, the source line 154 and the drain line 155 are provided, in the real transistor section 301. Note that as described in the second embodiment, the planarization of the insulating layer 114 may be performed.

Next, as illustrated in FIG. 8E, the strain measuring region 121 and the reference information measuring region 122 are formed on the Si substrate 111, in the strain measuring section 302. As a method of forming the strain measuring region 121 and the reference information measuring region 122, the method described in the first embodiment (FIB processing) or the like may be used.

In the process of manufacturing the semiconductor device 101, a failure may occur in a transistor of the real transistor section 301. In the present embodiment, such a defective transistor may be diverted to a strain measuring region 121 of the strain measuring section 302.

In this case, there is no need for forming the strain measuring region 121 in FIG. 8E. Alternatively, processing must be performed after testing the transistor of the real transistor section 301, in order to divert the defective transistor to the strain measuring region 121. For example, the gate electrode 152 and the like are removed or thinned by ion etching or the like, in order to prevent the gate electrode 152 and the like from disturbing electron beam diffraction. Thereby, there is formed the strain measuring region 121 diverted from the defective transistor.

This technique has an advantage that a defective transistor can be put in effective use. This technique is effective when, for example, the circuit area of the semiconductor device 101 has no room for such a strain measuring region 121 as shown in FIG. 8E to be formed therein.

As described above, the embodiments of the present invention provide a structure preferred for strain measurement, with regard to a semiconductor device including a strained semiconductor layer.

What is claimed is:

1. A semiconductor device comprising:
a strained semiconductor layer formed on a substrate; and
a strain measuring region, provided on the substrate, for measuring a strain of the semiconductor layer.

2. The semiconductor device according to claim 1, further comprising:
a reference information measuring region, provided on the substrate, for measuring reference information for evaluating the strain of the semiconductor layer.

3. A semiconductor device comprising:
an insulating layer formed on a substrate;
an island-shaped strained semiconductor layer formed on the insulating layer; and
a strain measuring region, provided on the substrate, for measuring a strain of the semiconductor layer, the strain measuring region having the semiconductor layer, wherein at least a part of the substrate below the semiconductor layer is removed or thinned.

4. The semiconductor device according to claim 3, further comprising:
a reference information measuring region, provided on the substrate, for measuring reference information for evaluating the strain of the semiconductor layer, wherein at least a part of the insulating layer is removed and the substrate is thinned.

5. The semiconductor device according to claim 2, wherein
the strain measuring region is a region for measuring the strain of the semiconductor layer, by irradiating a beam at the strain measuring region, and
the reference information measuring region is a region for measuring reference information for evaluating the strain of the semiconductor layer, by irradiating the beam at the reference information measuring region.

6. The semiconductor device according to claim 5, wherein the beam is such that a two-dimensional diffraction image of the beam can be obtained by irradiating the beam at the strain measuring region or the reference information measuring region.

7. The semiconductor device according to claim 4, wherein the substrate is thinned in the reference information measuring region to such a thickness as to enable diffraction of a beam to be used.

8. The semiconductor device according to claim 1, wherein the semiconductor layer is sandwiched between an insulating layer adjacent to the bottom surface of the semiconductor layer and an insulating layer adjacent to the top surface of the semiconductor layer.

9. The semiconductor device according to claim 8, wherein the total thickness of the insulating layer adjacent to the bottom surface of the semiconductor layer and the insulating layer adjacent to the top surface of the semiconductor layer is no greater than 1000 nm in terms of the thickness of silicon dioxide.

10. The semiconductor device according to claim 8, wherein the thickness of the semiconductor layer is no greater than 500 nm.

11. The semiconductor device according to claim 8, wherein the thickness of the insulating layer adjacent to the top surface of the semiconductor layer is no greater than twice the thickness of the insulating layer adjacent to the bottom surface of the semiconductor layer, and is greater than or equal to the thickness of the semiconductor layer.

12. The semiconductor device according to claim 8, wherein the insulating layer adjacent to the top surface of the semiconductor layer is planarized after being formed on the semiconductor layer.

13. The semiconductor device according to claim 1, wherein
a uniaxially-strained region having a uniaxial strain being measured or a uniaxial strain detecting region for detecting the presence or absence of a uniaxial strain, is provided in the semiconductor layer,
a region wherein the substrate is removed or thinned exists below the uniaxially-strained region or the uniaxial strain detecting region, and
the substrate exists below both ends of the semiconductor layer in the direction of the uniaxial strain.

14. The semiconductor device according to claim 1, wherein
a uniaxially-strained region having a uniaxial strain being measured or a uniaxial strain detecting region for detecting the presence or absence of a uniaxial strain, is provided in the semiconductor layer,
first and second biaxially-strained regions having biaxial strains, are provided at both ends of the semiconductor layer in the direction of the uniaxial strain,
a region wherein the substrate is removed or thinned exists below the uniaxially-strained region or the uniaxial strain detecting region,
a region wherein the substrate is present exists below the first biaxially-strained region, and
a region wherein the substrate is present exists below the second biaxially-strained region.

15. A semiconductor device comprising:
a substrate;
a strained semiconductor layer formed on the substrate, in a real transistor section on the substrate;
a gate insulating film formed on the semiconductor layer, in the real transistor section on the substrate;
a gate electrode formed on the gate insulating film, in the real transistor section on the substrate;
a strained semiconductor layer formed on the substrate, in a strain measuring section on the substrate;
a strain measuring region, provided in the strain measuring section on the substrate, for measuring a strain of the semiconductor layer; and
a reference information measuring region, provided in the strain measuring section on the substrate, for measuring reference information for evaluating the strain of the semiconductor layer.

16. A method of manufacturing a semiconductor device, the method comprising:
forming a strained semiconductor layer on a substrate; and
providing, on the substrate, a strain measuring region for measuring a strain of the semiconductor layer.

17. The method according to claim 16, further comprising:
providing, on the substrate, a reference information measuring region for measuring reference information for evaluating the strain of the semiconductor layer.

18. A method of manufacturing a semiconductor device, the method comprising:
preparing a substrate whereon an insulating layer is formed;
forming an island-shaped strained semiconductor layer on the insulating layer; and
providing, on the substrate, a strain measuring region for measuring a strain of the semiconductor layer, the strain measuring region having the semiconductor layer, wherein at least a part of the substrate below the semiconductor layer is removed or thinned.

19. The method according to claim 18, further comprising:
providing, on the substrate, a reference information measuring region for measuring reference information for evaluating the strain of the semiconductor layer, wherein at least a part of the insulating layer is removed and the substrate is thinned.

20. A method of manufacturing a semiconductor device, the method comprising:
preparing a substrate;
forming a strained semiconductor layer on the substrate, in a real transistor section on the substrate;
forming a gate insulating film on the semiconductor layer, in the real transistor section on the substrate;
forming a gate electrode on the gate insulating film, in the real transistor section on the substrate;
forming a strained semiconductor layer on the substrate, in a strain measuring section on the substrate;
providing a strain measuring region for measuring a strain of the semiconductor layer, in the strain measuring section on the substrate; and
providing a reference information measuring region for measuring reference information for evaluating the strain of the semiconductor layer, in the strain measuring section on the substrate.
